(19) United States
(12) Patent Application Publication
(10) Pub. No.: US 2017/0063383 A1
(43) Pub. Date: Mar. 2, 2017

(54) PHASE SYNCHRONIZATION WITH LOW FREQUENCY SAMPLING

(71) Applicant: QUALCOMM Incorporated, San Diego, CA (US)

(72) Inventors: Jeongsik Yang, San Jose, CA (US); Yashar Rajavi, Mountain View, CA (US); Keplin Victor Johansen, Campbell, CA (US); Ara Bicakci, Belmont, CA (US)

(21) Appl. No.: 14/838,204

(22) Filed: Aug. 27, 2015

(51) Int. Cl. H03L 7/081; H03L 7/099; H04B 7/06; H04W 56/00; H04B 7/04

(52) U.S. Cl. CPC H03L 7/081; H04W 56/0015; H04B 7/0413; H04B 7/0617; H03L 7/099

(57) ABSTRACT

This disclosure provides a device and method for synchronizing local oscillator (LO) chains. The method can include sampling first I-data and first Q-data to generate first sampled I-data and first sampled Q-data based on a sampling clock signal. The method can also include calibrating the sampling clock signal based on the first sampled I-data and the first sampled Q-data to generate a first calibrated sampling clock signal, the first calibrated sampling clock signal indicating an optimal sample position to sample the first I-data and the first Q-data. The method can also include synchronizing a phase of the first LO chain and a second LO chain based on the first calibrated sampling clock signal.

### BACKGROUND

Technical Field

This disclosure relates to radio frequency (RF) electronic circuits. More particularly, this disclosure relates to synchronizing signals.

Related Art

Wireless communication networks are widely deployed to provide various communication services such as telephony, video, data, and messaging, among other services. Such networks can often be multiple access networks, supporting communications for multiple users by sharing the available network resources. For example, one network may be a wireless local area network (WLAN) in accordance with the Institute of Electrical and Electronics Engineers (IEEE) 802.11 standard (e.g., Wi-Fi) or a wireless personal area network (WPAN) in accordance with the IEEE 802.15 standard. Another example wireless network may be a 3G (the third generation of mobile phone standards and technology), 4G, or later generation system, which may provide network service via any one of various radio access technologies (RATs) including EVDO (Evolution-Data Optimized), 1×RTT (1 times Radio Transmission Technology, or simply 1×), W-CDMA (Wideband Code Division Multiple Access), UMTS-TDD (Universal Mobile Telecommunications System—Time Division Duplexing), HSPA (High Speed Packet Access), GPRS (General Packet Radio Service), or EDGE (Enhanced Data rates for Global Evolution). The 3G network is a wide area cellular telephone network that evolved to incorporate high-speed internet access and video telephony, in addition to voice calls. Furthermore, a 3G network may be more established and provide larger coverage areas than other network systems. Such multiple access networks may also include code division multiple access (CDMA) systems, time division multiple access (TDMA) systems, frequency division multiple access (FDMA) systems, orthogonal frequency division multiple access (OFDMA) systems, single-carrier FDMA (SC-FDMA) networks, space division multiple access (SDMA), and 3rd Generation Partnership Project (3GPP) Long Term Evolution (LTE) networks, Long Term Evolution Advanced (LTE-A) networks.

Certain radio frequency front-ends (RFFEs) used for multi-user (MU) multiple-input multiple-output (MIMO) or MU-MIMO, for example, can have multiple receiver (RX) paths, multiple transmitter (TX) paths, or multiple transceiver paths, generally referred to herein as chains. Each of these paths in a multi-chain RFFE may have its own local oscillator (LO). The various LOs may be generated from a single voltage-controlled oscillator (VCO) using, for example, a divide-by-2 (Div2) frequency divider associated with each path. Although all of the frequency dividers may output the same frequency LO, each divider may arbitrarily start-up either in-phase (0°) or out-of-phase) (180° relative to another divider. In order to achieve particular capabilities or perform certain functions, such as beamforming, it may be desirable to operate the dividers in-phase.

### SUMMARY

In general, certain aspects of the present disclosure generally relate to detecting and adjusting phase shift between signals, such as local oscillator (LO) signals of adjacent receiver, transmitter, or transceiver paths frequency divided down from a voltage-controlled oscillator (VCO) signal. In some embodiments, all local oscillating signals can be phase-corrected such that each LO chain is in-phase for proper MIMO operation. More specifically, this disclosure describes systems and methods related to LO phase synchronization for beamforming applications or removing bi-modal direct current (DC) offset by using low frequency sampling. The systems, methods, and devices of this disclosure each have several innovative aspects, no single one of which is solely responsible for the desirable attributes disclosed herein.

One aspect of the disclosure provides a method for local oscillator (LO) phase synchronization. The method can include sampling first I-data and first Q-data from an input signal to generate first sampled I-data and first sampled Q-data based on a sampling clock signal. The method can also include calibrating the sampling clock signal based on the first sampled I-data and the first sampled Q-data to generate a first calibrated sampling clock signal, the first calibrated sampling clock signal indicating an optimal sample position to sample the first I-data and the first Q-data. The method can also include synchronizing a phase of the first LO chain and a second LO chain based on the first calibrated sampling clock signal.

Another aspect of the disclosure provides a device for LO phase synchronization. The device can have a plurality of samplers configured to sample first I-data and first Q-data for a first LO chain to generate first sampled I-data and first sampled Q-data based on a sampling clock signal. The device can also have a controller operably coupled the plurality of samplers. The controller can calibrate the sampling clock signal based on the first sampled I-data and the first sampled Q-data to generate a first calibrated sampling clock signal, the first calibrated sampling clock signal indicating an optimal sample position of the first I-data and the first Q-data. The controller can also synchronize a phase of the first LO chain and a second LO chain based on the calibrated sampling clock signal.

Another aspect of the disclosure provides an apparatus for LO phase synchronization. The apparatus can have means for sampling first I-data and first Q-data for a first LO chain to generate first sampled I-data and first sampled Q-data based on the sampling clock signal. The apparatus can also have means for sampling second I-data and second Q-data for a second LO chain to generate second sampled I-data and second sampled Q-data based on the sampling clock signal. The apparatus can also have means for calibrating the sampling clock signal based on the first sampled I-data and the first sampled Q-data to generate a first calibrated sampling clock signal, the means for calibrating further configured to calibrate the sampling clock signal based on the second sampled I-data and the second sampled Q-data to generate a second calibrated sampling clock signal. The apparatus can also have means for synchronizing a phase of the first LO chain and the second LO chain based on the first calibrated sampling clock signal.

Another aspect of the disclosure provides a method for LO phase synchronization. The method can include dividing an input signal into I-data and Q-data for each of a first LO chain and a second LO chain using a respective first LO divider and second LO divider. The I-data and the Q-data of the first LO chain having a first phase and the I-data and the Q-data of the second LO chain having a second phase. The method can also include sampling the I-data and the Q-data of the first LO chain and the second LO chain to generate sampled I-data and sampled Q-data for each of the first LO chain and the second LO chain based on a sampling clock signal. The method can also include calibrating the sampling clock signal based the sampled I-data and the sampled Q-data for each of the first LO chain and the second LO chain to generate a first calibrated sampling clock signal for the first LO chain, and a second calibrated sampling clock signal for the second LO chain. The method can also include synchronizing the first phase and the second phase based on the first calibrated sampling clock signal and the second calibrated sampling clock signal by flipping one of the first phase and the second phase.

Other features and advantages of the present disclosure should be apparent from the following description which illustrates, by way of example, aspects of the disclosure.

### BRIEF DESCRIPTION OF THE FIGURES

The details of embodiments of the present disclosure, both as to their structure and operation, may be gleaned in part by study of the accompanying drawings, in which like reference numerals refer to like parts, and in which:

FIG. 1 is a illustrative depiction of a wireless communications network;

FIG. 2 is a functional block diagram of an access point and a base station of FIG. 1; and

FIG. 3 is a functional block diagram of a local oscillator phase synchronization circuit;

FIG. 4 is a representation of the time relationship between I-data and Q-data signals of a local oscillator chain and a delayed sample clock signal;

FIG. 5 is a flowchart of a method for delay calibration and phase synchronization; and

FIG. 6 is a timing diagram depicting the delay calibration and LO phase synchronization of FIG. 5.

### DETAILED DESCRIPTION

The detailed description set forth below, in connection with the accompanying drawings, is intended as a description of various embodiments and is not intended to represent the only embodiments in which the disclosure may be practiced. The detailed description includes specific details for the purpose of providing a thorough understanding of the embodiments. Based on the following description, one skilled in the art should appreciate that an aspect disclosed herein may be implemented independently of any other aspects and that two or more of these aspects may be combined in various ways. For example, an apparatus or device may be implemented or a method may be practiced using any number of the aspects set forth herein. In addition, such an apparatus may be implemented or such a method may be practiced using other structure, functionality, or structure and functionality in addition to or other than one or more of the aspects set forth herein. Furthermore, an aspect may comprise at least one element of a claim. In some instances, well-known structures and components are shown in simplified form for brevity of description.

In a MU-MIMO system, multiple transmitters, receivers, transceivers can be present, each having its own LO signal. A VCO input signal can be divided down (e.g., in frequency) to provide the LO signals, referred to herein as LO chains, when associated with additional circuitry. In order to maintain synchronization and allow proper MIMO functionality and beamforming in, for example, SDMA, the LO signals require the same frequency and phase. In certain architectures, a direct current (DC) offset can result from an LO that leaks energy back to the antenna via an electromagnetic coupling with the antenna. This DC offset can then re-enter the mixer. When this leaked signal component is mixed with itself, a component of the resulting signal is a 0 Hz DC signal. The DC offset can sometimes be strong enough to disrupt the baseband amplifiers of the transmitter/receiver/transceiver and disrupt the signal. In some examples, this DC offset randomly flips between two distinct values creating a “bimodal DC offset.” When the LO is not synchronized this phenomenon is exacerbated and is detrimental to MIMO communications.

In some examples, LO chain synchronization can require high frequency LO routing and high frequency sampling in the 1-5 gigahertz (GHz) range. Such high frequency levels can increase production cost and complexity due to hardware requirements. As disclosed herein, the phases of multiple LO chains can be synchronized using low frequency sampling. For example, “low frequency sampling” as used herein can refer to frequencies of just a few megahertz (MHz), as in a digital clock in an integrated circuit (IC). For example, a low frequency sampling clock can operate in frequency ranges from 10 kilohertz (kHz) to approximately 100 megahertz (MHz). The low frequency sampling can eliminate the need for high frequency LO routing and thus decrease system requirements.

In some embodiments frequency dividers can be implemented to divide a signal provided by, for example, a VCO, into multiple separate LO signals (e.g., LO chains). In some embodiments, a divide-by-two (div2) frequency divider can be used to divide the VCO input signal. In some examples however, the multiple frequency dividers can produce different phases due to the initial condition of the delay flip-flop (DFF). If, for example, two div2 dividers are implemented in separate LO chains, the two LO chains may have as much as 180 phase differential. In some embodiments, n-number of LO chains can be implemented, where n is an integer.

As described herein, the frequency dividers in conjunction with an incremental delay imparted on data sampling can allow for proper phase synchronization of each of the LO chains and eliminate the bimodal DC offset.

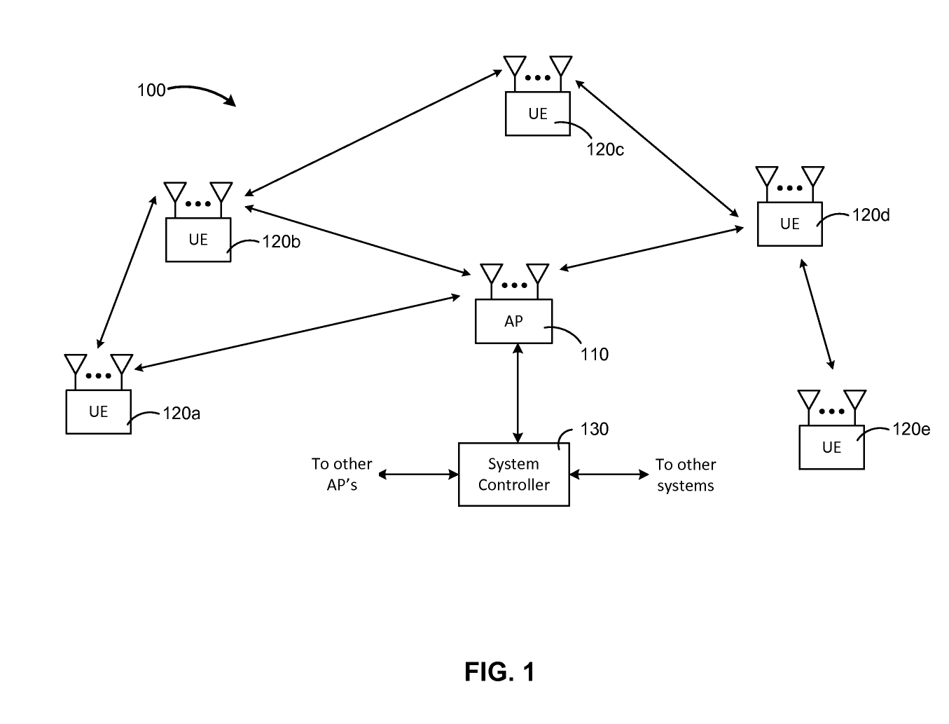

FIG. 1 is an illustrative depiction of a wireless communications network. A For simplicity, only one access point 110 is shown in FIG. 1. Communications system (system) 100 can have an access point (AP) 110. The AP 110 is generally a fixed station that can also be referred to as a base station (BS), an evolved Node B (eNB), or some other terminology depending on the communication protocol.

The AP 110 can communicate with a plurality of user terminals (UT) 120a-120e (collectively UTs 120) within the system 100. The UTs 120 can be fixed or mobile and the number of UTs 120 in the system 100 should not be considered limiting. The UTs 120 can also be referred to as a mobile station (MS), an access terminal (AT), user equipment (UE), a station (STA), a client, a wireless device, or some other terminology depending on the communication protocol. The UTs 120 can be a wireless device, such as a cellular phone, a personal digital assistant (PDA), a handheld device, a wireless modem, a laptop computer, a tablet, a personal computer, etc.

The AP 110 can communicate with one or more UTs 120 at any given moment on the downlink (DL) and uplink (UL). The DL, or forward link, generally describes communications from the AP 110 to the UTs 120. The UL, or reverse link, generally described the communication link from the UTs 120 to the AP 110. In addition, the UT 120a can also communicate peer-to-peer with one of the other UTs 120b-120e.

The system 100 can also comprise a system controller 130. The system controller 130 can couple to the AP 110 and provide coordination and control from the AP 110 to another AP or to other systems 100.

The system 100 can employ multiple transmit and multiple receive antennas for data transmission on the UL and DL. The AP 110 can be equipped with a number of antennas to achieve transmit diversity for DL transmissions and/or receive diversity for UL transmissions. The UTs 120 can thus receive DL transmissions and transmit UL transmissions. Each UT 120 can transmit user-specific data to the AP 110 and/or receives user-specific data from the AP 110. In certain systems, such as MIMO for example, the AP 110 and each UT 120a-120e can be equipped with one or more antennas.

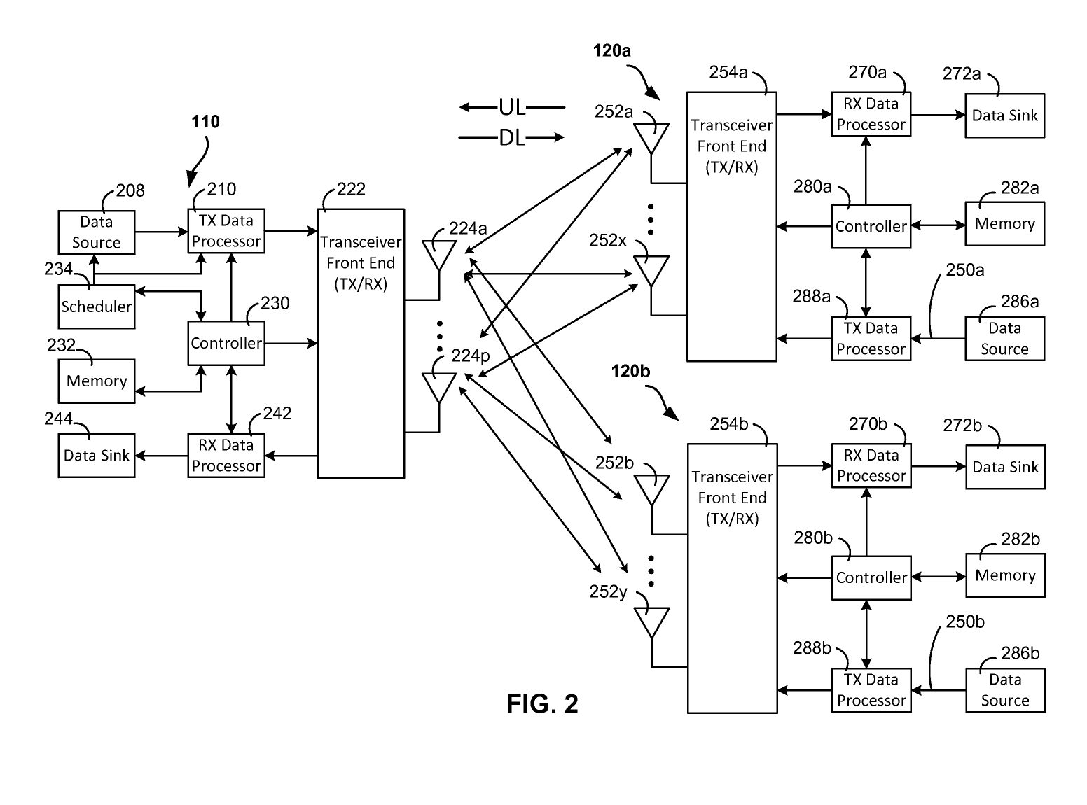

FIG. 2 is a functional block diagram of the access point and two user terminals of FIG. 1. As shown, the AP 110 can communicate to one or more UTs 120, for example, the UT 120a and the UT 120b within the system 100. The AP 110 is equipped with a number Nₚ antennas 224a through 224p. The UT 120a is equipped with a number Nₓ antennas 252a through 252x, and the UT 120b is equipped with N_{y} antennas 252b through 252y. For purposes of this description, reference numerals with a letter may generally be used to refer to individual components (e.g., the antenna 252a). The same components can be generally referred to collectively using their respective reference numeral only (e.g., the antennas 252).

The AP 110 can be a transmitting entity for the DL and a receiving entity for the UL. Each of the UTs 120 can be a transmitting entity for the UL and a receiving entity for the DL. As used herein, a “transmitting entity” generally refers to an independently operated apparatus or device capable of transmitting data via a frequency channel. Similarly, a “receiving entity” as used herein generally refers to an independently operated apparatus or device capable of receiving data via the same or a different frequency channel.

As used herein, the subscript “dn” generally denotes the DL, the subscript “up” generally denotes the UL. Accordingly, a number “Nᵤₚ” generally denotes a number of UTs 120 selected for simultaneous transmission on the uplink, while a number “N” generally refers to a number of the UTs 120 selected for simultaneous transmission on the DL. In some embodiments, Nᵤₚ may or may not be equal to N_{dn}, and Nᵤₚ and N_{dn} may be static values or can change for each scheduling interval. Beamforming, beam-steering, or some other spatial processing technique (e.g., MU-MIMO, SDMA) can be used at the AP 110 and the UTs 120.

Each of the UTs 120 can comprise a data source 286 operably coupled to a transmit (TX) data processor 288. On the UL, the data source 286 can supply traffic data 250 to the TX data processor 288 and control data from a controller 280. The TX data processor 288 can process (e.g., encodes, interleaves, modulates, etc.) the traffic data {dᵤₚ} for the UT 120 based on coding and modulation schemes (MCS) associated with the rate selected for the UT 120. The TX data processor 288 can also provide a data symbol stream {sᵤₚ} for one or more of the antennas 252.

The UTs 120 can also have a controller 280 operably coupled to the TX data processor 288. The controller 280 can provide control and synchronization signals for the transmission and reception of coded signals. The controller 280 can control the routing within the transceiver front-end 254. The controller 280 can also be operably coupled to a memory 282. The memory 282 can store data, information, and computer-readable instructions that may be required for performing the various processes disclosed herein.

The UTs 120 can also have a (TX/RX) 254 (also referred to herein as a radio frequency front-end (RFFE)) is operably coupled to the TX data processor 288 and the controller 280. The transceiver front-end 254 can be configured to receive and process (e.g., converts to analog, amplifies, filters, and frequency upconverts) a respective symbol stream to generate an UL signal. The transceiver front-end 254 may also route the UL signal to one of the Nₓ or N_{y} antennas 252 for transmit diversity via an RF switch, for example.

The number Nᵤₚ of user terminals may be scheduled for simultaneous transmission on the UL. Each of these user terminals transmits its set of processed symbol streams on the uplink to the access point.

At the AP 110, a number Nᵤₚ antennas 224a through 224p can receive the UL signals from all Nᵤₚ UTs 120 transmitting on the UL. For receive diversity, a transceiver front-end 222 operably coupled to the antennas 224 can select signals received from one of the antennas 224 for processing. In certain aspects of the disclosure, combinations of the signals received from multiple antennas 224 may be combined for enhanced receive diversity.

The transceiver front-end 222 can also perform processing complementary to that performed by the transceiver front-end 254 of the UTs 120 and can provide a recovered UL data symbol stream. The recovered uplink data symbol stream is an estimate of a data symbol stream {sᵤₚ} transmitted by one or more of the UTs 120.

The AP 110 can also have a receive (RX) data processor 242 operably coupled to the transceiver front end 222. The RX data processor 242 can process (e.g., demodulates, deinterleaves, and decodes) the recovered UL data symbol stream in accordance with the rate (e.g., MCS) used for that stream to obtain decoded data. The AP 110 can also have a data sink 244 for storage and data buffering of the decoded data. The data sink 244 and the controller 230 can be operably coupled to the RX data processor 242. The decoded data for each UT 120 can be provided to the data sink 244 for storage and/or further use by the AP 110.

The AP 110 can also have a controller 230. The controller 230 can control and direct the processes within the AP 110 by executing stored code for various operations. The controller 230 can also be operably coupled to a memory 232 that can be configured to store data, information, and executable instructions for use by the controller 230 in performing the various processes disclosed herein.

The AP 110 can also have a TX data processor 210 operably coupled to the transceiver front end 222 and the controller 230. On the DL, the TX data processor 210 can receive traffic data from a data source 208 for N_{dn} UTs 120 scheduled for DL transmission and control data from the controller 230. The AP 110 can also have a scheduler 234 coupled to the controller 230 and the data source 208. The scheduler 234 can aid in the control of the flow of traffic data from the data source 208 to the TX data processor 210. The various types of data may be sent on different transport channels.

The TX data processor 210 can process (e.g., encodes, interleaves, and modulates) the traffic data for each UT 120 based on the rate selected for that user terminal. The TX data processor 210 can provide a DL data symbol streams for one of more of the N_{dn} UTs 120 to be transmitted from one of the Nₚ antennas 224 at the AP 110. The transceiver front-end 222 receives and processes (e.g., converts to analog, amplifies, filters, and frequency upconverts) the symbol stream to generate a DL signal. The transceiver front-end 222 can also route the DL signal to one or more of the N_{dn} antennas 224 for transmit diversity via an RF switch, for example. The controller 230 can control the routing within the transceiver front-end 222.

At each UT 120, Nₓ or N_{y} antennas 252 can receive the DL signals from the AP 110. For receive diversity at the UTs 120, the transceiver front-end 254 can select signals received from one of the antennas 252 for processing.

In certain aspects of the disclosure, a combination of the signals received from multiple antennas 252 can be combined for enhanced receive diversity. The transceiver front-end 254 at the UTs 120 can also perform processing complementary to that performed by the transceiver front-end 222 of the AP 110. The transceiver front-end 254 can also and provide a recovered DL data symbol stream. The RX data processor 270 processes (e.g., demodulates, deinterleaves, and decodes) the recovered downlink data symbol stream to obtain decoded data for the UT 120.

Certain Wireless Local Area Network (WLAN) applications, especially those for use in MU-MIMO or other applications using RF beamforming, can require the use of local oscillators (LO) and multiple frequency dividers. MIMO and other beamforming applications may require each LO path to be synchronized and avoid bi-modal DC offset. Some LO phase alignment is implemented using mixer-based phase detection. This can require high-frequency (2-5 GHz) LO routing from LO dividers to the phase detector. Certain implementations also have significant delay variations leading to failure of the phase detector as delay is difficult to match at the LO frequency. Such an arrangement can also be expensive in both materials and space, as the required mixer, filter, and comparator require more physical area to implement.

In order to enable diversity and proper beamforming in MIMO or SDMA, for example, the AP 110 and the UTs 120 need to synchronize transmissions (UL and DL). In order to synchronize transmissions, the AP 110 and the UTs 120 can have one or more VCOs that provide a signal, or clock signal, having a steady or constant frequency. The VCO can be implemented within the controller 230 or the transceiver front end 222 of the AP 110 on the DL. A similar VCO can be implemented within the controller 280 or the transceiver front end 254 of the UTs 120 on the UL. As each of the antennas 224 and the antennas 252 may each have their own transceiver, a respective number of LO chains may be needed at both the AP 110 and the UTs 120. Each of the LO chains within the AP 110 and the UTs 120 need to be synchronized in frequency and phase.

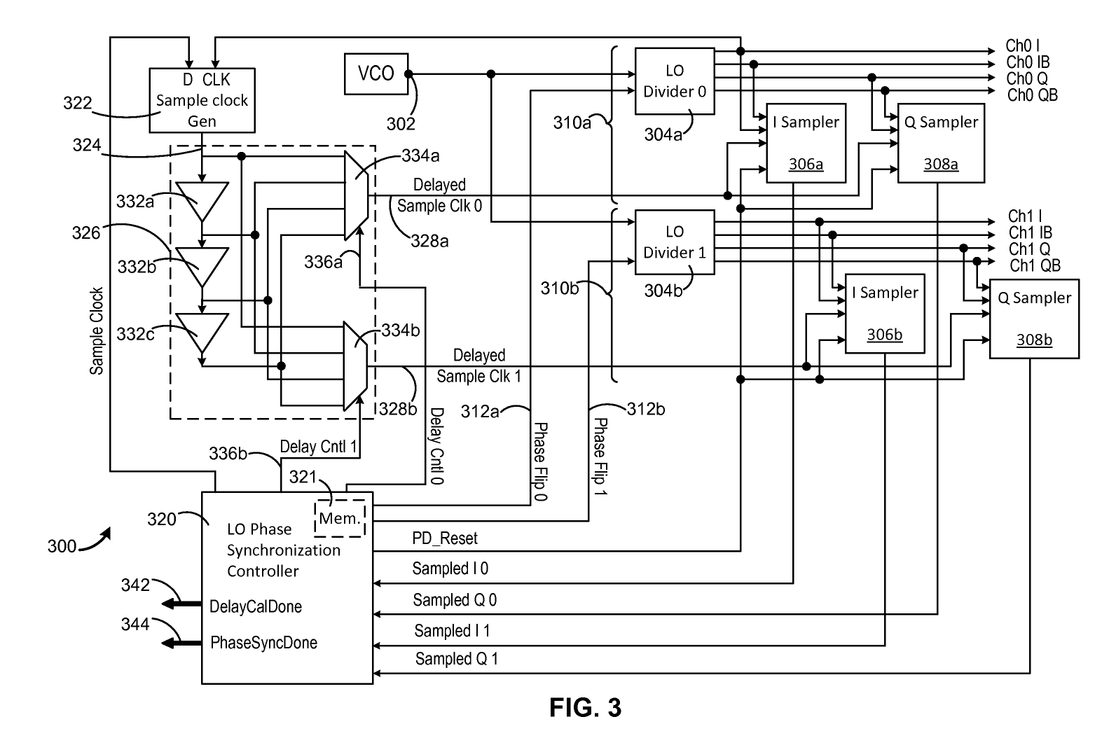

FIG. 3 is a functional block diagram of a local oscillator phase synchronization circuit. A phase synchronization circuit (circuit) 300 is shown having VCO input 302. The VCO input 302 can receive a VCO signal for use in synchronizing individual transceivers within, for example, the transceiver front-end 222 or the transceiver front-end 254. The VCO input 302 can be, for example, a digital clock input. Such a digital input can be a signal in the two to five (2-5) gigahertz (GHz) range, for example.

The VCO input 302 can be split into a plurality of LO chains. An LO chain 310a and an LO chain 310b are indicated using brackets. The LO chain 310a and the LO chain 310b can be collectively referred to as the LO chains 310. Alternatively, the LO chain 310a can be referred to as channel (Ch) zero (Ch0) while the LO chain 310b can be referred to as channel one (Ch1). Only the two LO chains 310 are shown, however an LO chain 310 can be implemented for each antenna 252 implemented in the UT 120 and each antenna 224 implemented in the AP 110.

Each LO chain 310 can have an LO divider 304, shown as an LO divider 304a and an LO divider 304b (collectively LO dividers 304). The LO dividers 304 can be implemented as a divide-by-two (div2) circuit configured to convert the VCO input 302 into a signal having half the frequency of the VCO signal. In some embodiments, other divide-by-x counters can be implemented to derive a different resulting signal. A div2 counter is used herein as an example.

Each LO divider 304 can provide I (in-phase) data and Q (quadrature) data describing 0° phase (I) and 90° phase (Q) of each channel (Ch0, Ch1). The LO dividers 304 can produce, for example, I, I-bar (IB), Q, and Q-bar (QB) data. The IB and QB data indicate an inverse signal, generating an output signal with 180° phase difference from the corresponding I-data and Q-data. In general the Q-data leads or lags its respective I-data by 90° (quadrature) in phase.

The LO chains 310 can further have a respective sampler for each of the I- and Q-data, resulting in two samplers per channel. The LO chain 310a can have an I-sampler 306a and an Q-sampler 308a. Similarly the LO chain 310b can have an I-sampler 306b and a Q-sampler 308b. The I-samplers 306a, 306b can be collectively referred to as I-sampler(s) 306 while the Q-samplers 308a, 308b can be collectively referred to as Q-sampler(s) 308.

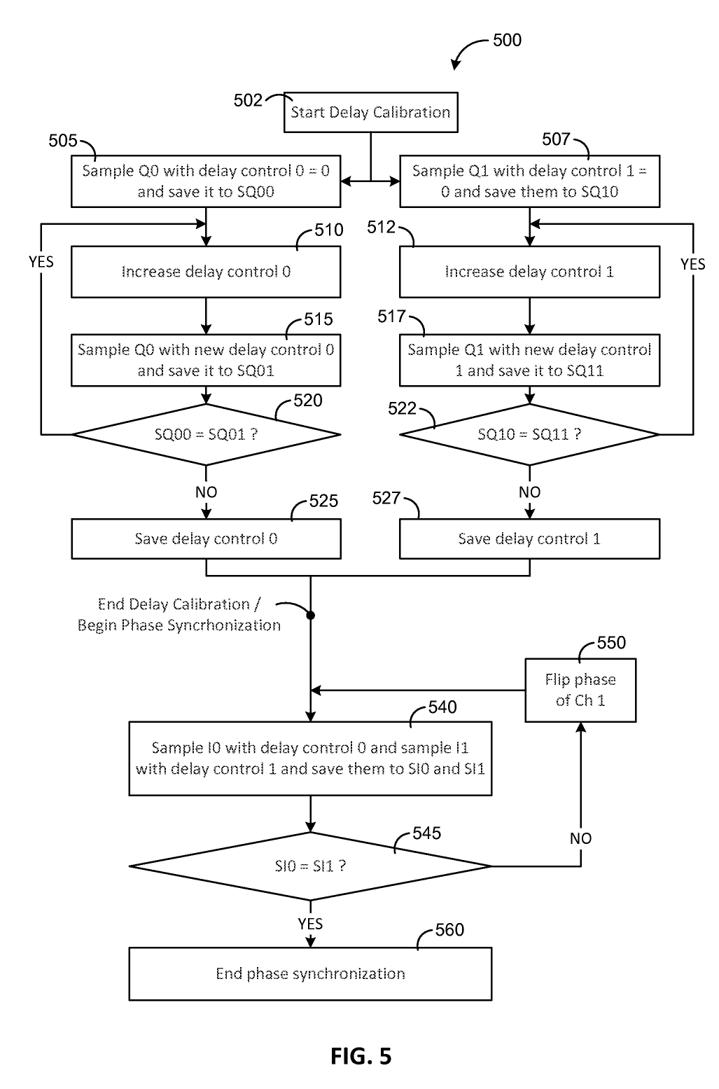

Each of the I-samplers 306 and the Q-samplers 308 can output sampled I-data and sampled Q-data based on a sampling rate. The sampling rate can be determined by a sample clock signal (described below). The output of the I-samplers 306 and the Q-samplers 308 can be fed back to a LO phase synchronization controller (“synch controller”) 320 as sampled I-data and sampled Q-data for each channel (Ch0, Ch1). The synch controller 320 can also have a memory 321. The memory 321 can be configured to store or buffer delay calibration and synchronization information associated with the I-data and the Q-data. The synch controller 320 can then control the sampling rate of the I-samplers 306 and the Q-samplers 308 based at least in part on the sampled I-data and the sampled Q-data. The synch controller 320 can also be configured to determine a phase-flip function 312a, 312b (collectively phase-flip 312) of each of the respective LO dividers 304. The phase flip function 312 can be used during the phase synchronization process described below in connection with FIG. 5. In particular, the phase-flip function 312 can flip the phase of the data (e.g., I-data or Q-data) of one or more of the corresponding LO chains 310. In some embodiments the phase of only one of the two LO chains 310 may be flipped. In some other embodiments, where more than two LO chains 310 are present, the phase of more than one LO chain 310 may be flipped in order to synchronize the LO chains 310.

The circuit 300 can also have a sample clock generator 322. The sample clock generator 322 can receive control inputs from the synch controller 320 and adjust the frequency of the sample clock signal 324 supplied to the I-samplers 306 and the Q-samplers 308. The sample clock signal 324 can be a low frequency signal. As noted above, low frequency, as used herein can be in the range of 10 kHz to 100 MHz. In some other embodiments, the sampling clock signal 324 can operate in the 20-50 MHz frequency range. The term “low frequency” is noted in relation to some sampling clocks that can have much higher sampling frequencies in excess of 100 MHz, into the GHz range. The lower frequency requirements of the circuit 300 can simplify certain structural requirements of the circuit 300. Lower frequencies can also diminish power requirements of the circuit. In some embodiments, the sample clock generator 322 can be, for example, a VCO. In some embodiments, the sample clock signal 324 can be provided by another clock source.

In some embodiments, the sample clock signal 324 can be routed through a delay circuit 326 (shown in dashed lines) that can provide a series of incremental delays to the sample clock signal 324. The delay circuit 326 can be implemented as a series of delay buffers 332 (shown as delay buffers 332a, 332b, 332c) and delay controllers 334a, 334b. While three delay buffers 332a, 332b, 332c are shown, this number should not be considered limiting. In some embodiments, any number of delay buffers 332 can be used. The delay buffers 332 can each be configured to delay the sample clock signal 324 by predetermined amount or increment of time. In some embodiments, each of the delay buffers 332 can have the same incremental time delay imparted to the sample clock signal 324. In some other embodiments, the amount of delay imparted by each of the delay buffers 332 can be programmable or variable as determined by the synch controller 320. In some embodiments, the delay buffers 332 can each impart a predetermined amount of delay. The incremental amount of delay imparted by each of the delay buffers 332 can allow the synch controller 320 to incrementally adjust or calibrate a delayed sample clock signal 328 according to the delay calibration process (FIG. 5) without affecting the frequency of the sample clock signal 324 or the period of I-data or the Q-data samples.

The delayed sample clock signals 328 are shown as delayed sample clock signals 328a, 328b, corresponding to the Ch0 and the Ch1 LO chains 310. The delayed sample clock signal 328 can be delivered to the I-samplers 306 and the Q-samplers 308 to control the rate at which the I-data and Q-data is sampled. The delayed sample clock signals 328 can be used during a delay calibration process (FIG. 5) at the synch controller 320. The delay calibration process, as described below, can ensure that the I-data (or the Q-data) is sampled at an optimal point, for example, at the middle of the I-data high pulse. In this context, the term “high pulse” generally refers to the high value of the sample clock signal 324. For example, a clock signal can have a high (1) and a low (0) binary states. In some embodiments, the delay calibration can be applied to n-number of LO chains 310, where “n” is an integer. Additionally, the number of delay buffers 332 implemented in the circuit 300 can be proportional to a period of the LO signal divided by the delay of each buffer 332. The total amount of delay imparted on the delayed sample clock signal 328 can be proportional to a period of the LO signal divided by the amount of delay imparted by each of the delay buffers 332. In some embodiments, the total delay can be a predetermined value unrelated to the period of the LO signal. However, in some embodiments, the aggregate delay of all of the buffers 332 can be a delay value that is larger than half of the I-data or the Q-data, including at least one transition of the I-data or the Q-data. This aspect can be important for the delay calibration.

In some embodiments, the number of delay controllers 334 can correspond to the number of delayed sample clock signals 328 needed for respective LO chains 310. In the present example, two delay controllers 334 are shown, each having four inputs: the sample clock signal 324 and three incrementally delayed versions of the sample clock signal 324 (delayed sample clock signal 328).

In some embodiments, the delay controllers 334 can be configured to receive delay control signals 336 (shown as delay control signals 336a, 336b) from the synch controller 320. The delay control signals 336 can be used to select a desired amount of delay for each of the delayed sample clock signals 328 provided to the I-samplers 306 and the Q-samplers 308. The delayed sample clock signals 328 can then be used to optimize the sampling positions and sampling rate of each of the I-samplers 306 and/or the Q-samplers 308.

In certain embodiments, the optimal sampling position for the I-data is in the middle of the high I-data pulse. Due to the 90° lag of Q-data behind its corresponding I-data, the optimal sampling position for the I-data corresponds to the transition point (high-to-low or low-to-high, e.g., in a digital clock signal) of the Q-data. In some other embodiments, the converse is true: the optimal sampling position of the Q-data can be the determined using a transition of the I-data pulse. Either configuration can be used to determine the optimal sampling point for each LO chain (Ch0, Ch1).

The delayed sample clock signal 328 can be delivered to the I-samplers 306 and the Q-samplers 308. The I-samplers 306 and the Q-samplers 308 can then provide sampled I-data and sampled Q-data from each LO chain 310 to the synch controller 320 according to the delayed sample clock signal 328. The synch controller 320 can then conduct delay calibration and phase synchronization in order to synchronize the LO chains. These processes are described in connection with FIG. 5 below. Once the delay calibration is complete, the synch controller 320 can output a “DelayCalDone” output 342 indicating the delay calibration process is complete. In some embodiments, the DelayCalDone output 342 can be transmitted to the controller 230 (FIG. 2) or the controller 280 (FIG. 2) depending on whether the phase synchronization circuit is implemented at the AP 110 or the UTs 120. In some embodiments, the DelayCalDone output is a binary (e.g., 0/1) signal.

The synch controller 320 is also configured to output a “PhaseSyncDone” output 344 indicating that the phase synchronization of the LO chains 310 is complete. The PhaseSyncDone output 344 can also be sent to the controller 230 or the controller 280.

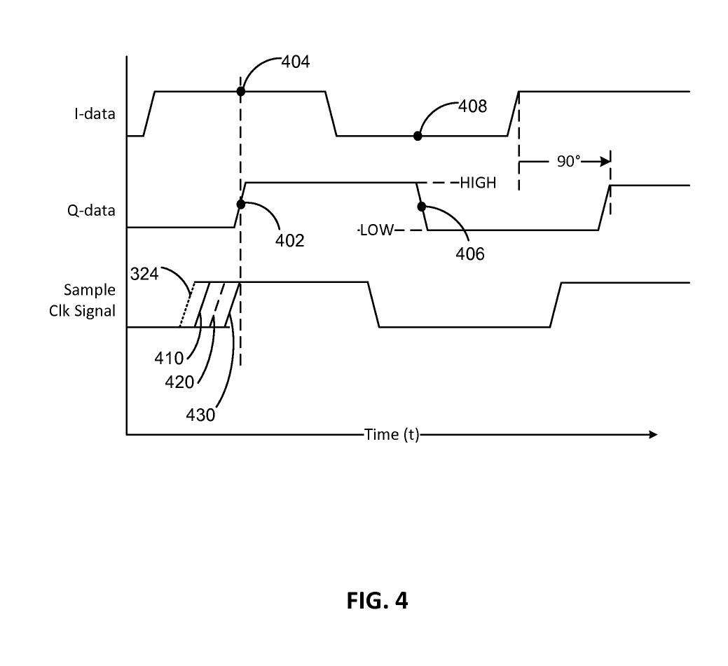

FIG. 4 is a representation of the time relationship between I-data and Q-data signals of a local oscillator chain and a delayed sample clock signal. As shown, the vertical axis shows exemplary I-data and Q-data signals plotted against the delayed sample clock signal 328. The amplitudes of the individual signals are for illustrative purposes and not necessarily drawn to scale. The horizontal axis indicates time (t) from left to right. Since the Q-data lags the I-data by 90° phase (quadrature) as shown, a low-to-high transition point 402 occurs in the Q-data coincident in time with the middle of the I-data high pulse. This indicates an optimal sample position 404 to sample the I-data. In some embodiments, the transition of the Q-data from high-to-low a point 406 can be used, indicating the middle of the corresponding I-data low pulse at point 408. The synch controller 320 can also use the transition point of the I-data to indicate an optimal sampling point for the Q-data. Therefore, as shown in FIG. 4, a high-to-low transition of I-data corresponds to the center of the Q-data high pulse, while the low-to-high transition of the I-data corresponds to the center of the Q-data low pulse.

The sample clock signal 324 is shown at the bottom of FIG. 4 having multiple time delays 410, 420, 430 applied. The sample clock signal 324 can be incrementally delayed from left to right using the delay buffers 332 (FIG. 3). The sample clock signal 324 with one or more of the time delays 410, 420, 430 applied can be referred to as the delayed sample clock signal 328.

The synch controller 320 can monitor the value of the sampled Q-data with an un-delayed version and delayed versions of the sample clock signal 324. The delay controllers 334 can incrementally apply the various time delays 410, 420, 430 to the sample clock signal 324 to calibrate the sample clock signal 324 to achieve the desired (optimal) sample position. As time delays (e.g., the delays 410, 420, 430) are incrementally added to the sample clock signal 324, the sample position can be move to the right, in time. The synch controller 320 can monitor the any changes in value of the Q-data sample (e.g., from low-to-high or high-to-low) with each of the various delays. Such a change in the Q-data sample value can indicate the transition point and the corresponding optimal sample positions 404, 408 for the I-data. FIG. 4 indicates that the use of the third time delay 430 added to the sample clock signal 324 results in a sample that can indicate a change in sample value from low-to-high of the Q-data (at point 402). This indicates to the synch controller 320 that the use of the third time delay 430 will provide the optimal sample position 404 for the I-data.

Therefore, the delay calibration process can be used to determine the Q-data transition by incrementally delaying the sample clock signal 324 (to provide delayed sample clock signal 328). The selected delayed sample clock signal 328 can then be used to sample the I-data for each of the LO chains 310 during the phase synchronization process. In some embodiments, the transition (from low-to-high or high-to-low) for the I-data can be used during delay calibration to sample the Q-data during phase synchronization.

FIG. 5 is a flowchart of a method for delay calibration and phase synchronization. A method 500 is shown beginning at block 502 with the start of delay calibration at the synch controller 320. Delay calibration can be completed for each LO chain 310 present in the synchronization circuit 300. Delay calibration is also completed for each pair of the I-samplers 306 and the Q-samplers 308. Accordingly, two parallel delay calibration processes are depicted in the method 500 corresponding to the LO chains 310 of FIG. 3. Additionally, the number of delay calibration processes can vary with the number of LO chains 310 present in the synchronization circuit 300.

At block 505, the Q-sampler 308a can sample the Ch0 Q-data with an (un-delayed) sample clock signal 324. This value, set as “delay control 0” equal to zero (0) can be set by the synch controller 320 and saved to the memory 321 as a first value of sampled Q-data for Ch0 (“SQ00”). At block 510, the synch controller 320 can increase the delay control 0 by an increment (e.g., the delay 410). The increment can correspond to one delay imparted by, for example, the delay buffer 322a. The Q-sampler 308a can then sample the Q-data with the new delay control 0 value and save it to the memory 321 as a value SQ01 at block 515.

At decision block 520, the synch controller 320 can compare the sampled Ch0 Q-data values SQ00 and SQ01. If the values of SQ00 and SQ01 are equal, then the method 500 returns to block 510 where the sample clock signal 324 is delayed further, adding another time increment (e.g., the time delay 420) to clock signal 324 to increase the delay in the delayed clock signal 328a. Accordingly, the synch controller 320 can command the Q-sampler 308a to repeatedly sample the Ch0 Q-data (of the LO chain 310a) to determine when the sampled value of Ch0 Q-data changes, indicating the transition of the Q-data from low-to-high, or high-to-low and the optimal sample position 404. For example, if the previous sampled data has a value of 0 and the current sampled data has a value of 1 or vice versa, this indicates the transition of the sample values between the previous delay control value and the current delay control value to the synch controller 320. Accordingly, the synch controller 320 can use either the previous delay control value or the current delay control value as the optimal sampling point. A single delay value (from, e.g., the delay buffer 332) can be the minimum resolution of the delay calibration.

If at decision block 520 the values of sampled Q-data are unequal (e.g., SQ00≠SQ01), this signals that the Q-sampler 308a sampled the Ch0 Q-data at a transition point, indicating the optimal sample position 404 for sampling Ch0 I-data, as described above. At block 525, this value can be saved as delay control 0 within the memory 321.

The same process can be completed for the Ch1 Q-data. At block 507, the Q-sampler 308b can sample the Ch1 Q-data using an un-delayed sample clock signal 324. The sampled value can be saved to the memory 321 as a value “SQ10.” At block 512, the synch controller 320 can increment the delay to the Q-sampler 308b of Ch1. At block 517, the Q-sampler 308b can again sample the Ch1 Q-data and save the sampled Q-data value as “SQ11” to the memory 321.

If at decision block 522 the SQ10 is equal to the SQ11 then the synch controller 320 can increment the delayed sample clock signal 328b, returning to block 512. The Q-sampler 308b can again sample the Ch1 Q-data using the new delay and save the sampled value to the memory 321.

At decision block 522, if the values of SQ10 and SQ11 are not equal, then the synch controller 320 determines that the Q-sampler 308b has sampled the Q-data at a transition point. Then at block 527, the synch controller 320 can save the delay value as delay control 1. In this way, the Q-sampler 308b can repeatedly sample the Ch1 Q-data until the optimal sampling point for the Ch1 I-data is determined. Once the delay control 0 and delay control 1 values are determined, the delay calibration portion of the method 500 ends.

At block 540, the synch controller 320 can command the I-samplers 306 to sample Ch0 and Ch1 I-data using the values of the delay control 0 and the delay control 1 saved at block 525 and block 527, respectively. The sampled values can be saved as values SI0 and SI1. At this point in the process, the synch control 320 has determined an optimal sampling point for the I-data and Q-data for each of the LO chains 310, Ch0 and Ch1. Accordingly, since each the LO chains 310 have the same frequency, if the sampled values of the Ch0/Ch1 I-data (SI0 and SI1) are not equal, this indicates the Ch0 I-data and the Ch0 I-data are 180° out of phase. Thus, at block 550, the synch controller 320 can command a phase flip of the Ch1 I-data, bringing the Ch0 I-data into phase with the Ch1 I-data, and producing synchronized LO signals from the LO chains 310. In some other embodiments, Ch0 can be flipped. In still other embodiments where more than two LO chains 310 are present, the phase flip of block 550 can be iterated for each LO chain 310 phase comparison. Once the phase synchronization is complete, the synch controller 320 can output a PhaseSyncDone output 344 at block 560, indicating that the phase synchronization is complete.

While the Q-data is used for delay calibration and finding the center point of each pulse of I-data (referred to herein as the “optimal sampling point”), the converse is also true.

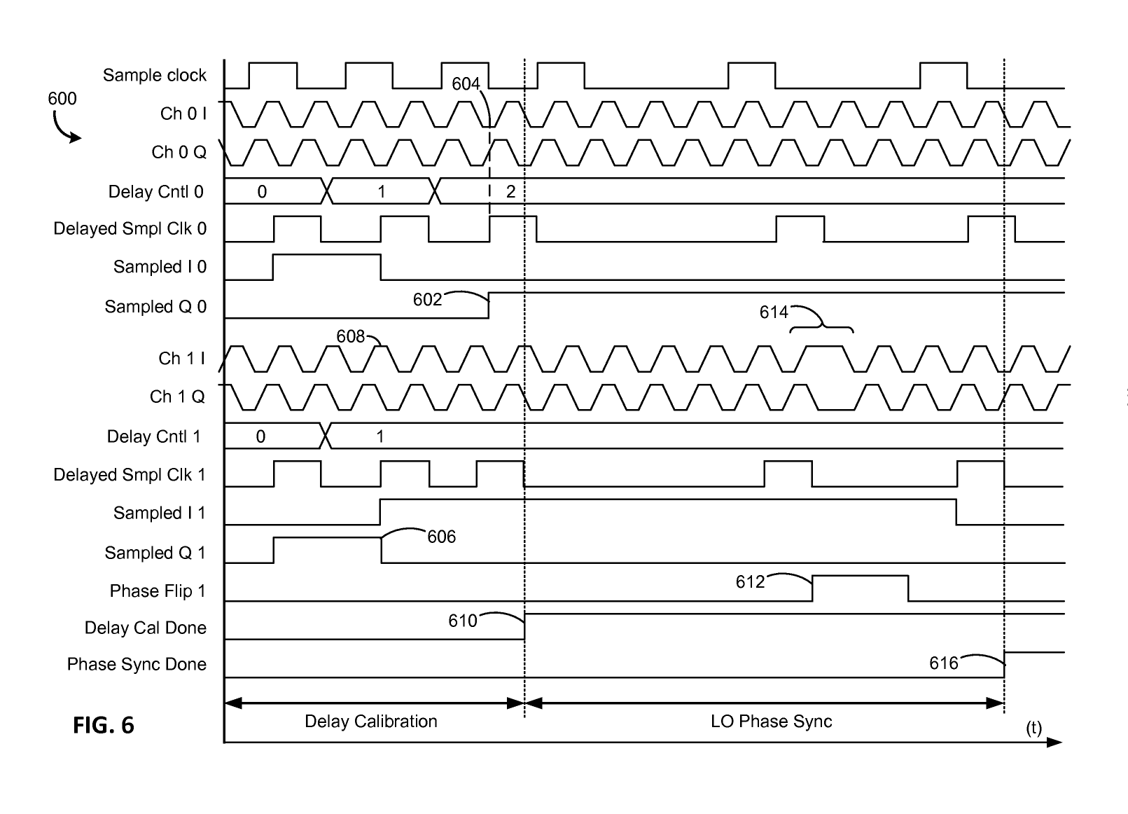

FIG. 6 is a timing diagram depicting the delay calibration and LO phase synchronization of FIG. 5. A timing diagram 600 depicts time (t) on the horizontal axis representing time zero (0) at the origin on the left of the diagram. The vertical axis indicates various signals present within the circuit 300 (FIG. 3) and their relative values coordinated in time. Each of the signals is labeled along the vertical axis of the diagram 600.

The diagram 600 depicts digital values for each of the signals. In some embodiments, the individual signals can have “high” and a “low” values represented as a one or zero (e.g., binary). The diagram 600 shows, in order from top to bottom, representations of the sample clock signal (Sample Clock), I-data for the LO chain 310a (Ch0 I), Q-data for the LO chain 310a (Ch0 Q), delay control signal 336a for the LO chain 310a (Delay Cntl 0), delayed sample clock 328a (Delayed Smpl Clk 0), sampled Ch0 I-data (Sampled I 0), sampled Ch0 Q-data (Sampled Q 0), I-data for the LO chain 310b (Ch1 I), Q-data for the LO chain 310b (Ch1 Q), delay control signal 336b (Delay Cntl 1), delayed sample clock 328b (Delay Smpl Clk 1), sampled Ch1 I-data (Sampled I 1), and sampled Ch1 Q-data (Sampled Q 1). The diagram 600 also shows the phase flip 312, DelayCalDone output 342, and the PhaseSyncDone output 344 as some of the outputs of the synch controller 320. As noted above, the DelayCalDone output 342 can be a binary signal indicating that the delay calibration is complete across all of the LO chains 310. Similarly, the PhaseSyncDone output 344 can indicate when the phase synchronization is complete across all of the LO chains 310. The point at which each of the of the DelayCalDone output 342 and the PhaseSyncDone output 344 switch from low-to-high values indicates such completion. This is indicated by vertical dotted lines. Accordingly, horizontal double-ended arrows indicate the subprocesses for delay calibration and phase synchronization.

As noted in FIG. 5, the sample clock signal 324 can be incrementally delayed at block 510 and block 512. The Delay Control 0 of FIG. 6 shows two delay increments (1, 2) corresponding to, for example, the delay buffers 332a, 332b (FIG. 3). As noted at decision block 520, the sampled value of Ch0 Q-data can be monitored until it changes value, as shown at point 602, indicating the transition point of the sampled Ch0 Q-data (e.g., the LO chain 310a). The transition point of the Ch0 Q-data corresponds to the middle of the pulse for the corresponding Ch0 I-data, at point 604. The point 604 is at a low value of the Ch0 I-data but it falls in the middle of the low pulse. As noted by block 525, sync controller 320 can save the delay value to the memory 321 and use it for subsequent Ch0 I-data sampling.

The same process can be enabled for the LO chain 310b. The diagram 600 also depicts the Delayed Sample Clk 1 having only one delay increment (e.g., increment 1) corresponding to, for example, the delay buffer 322a. As noted in block 512, the delay control 336b can increment the delay. The synch controller 320 can monitor the value of the sampled Ch1 Q-data at block 522. As the value of the sampled Ch1 Q-data changes from low-to-high or high-to-low, such as at point 606, this indicates the middle of the corresponding Ch1 I-data pulse, as shown at point 608. The synch controller 320 can save the delay value to the memory 321 and continue to sample the I-data at the center of the I-data pulse.

In some embodiments, the sampling process described above can also be used in the inverse scenario. For example, the synch controller 320 can monitor the value of the sampled I-data for a change in value. This can also indicate an optimal sampling point for corresponding Q-data, that is, in the center of the corresponding Q-data pulse.

As shown in the diagram 600, the Ch1 delay calibration is complete before the Ch0 delay calibration. Accordingly, for such an example where only the two LO chains 310 are present, delay calibration will be complete with the delay calibration of the last LO chain 310 present. In the present example, delay calibration is complete at the point 610, corresponding to the DelayCalDone 342 (FIG. 3).

Upon completion of the delay calibration for the two or more LO chains 310, the synch controller 320 can determine whether the LO chains 310 are in phase or out of phase. This can be done at block 540 and block 545 (FIG. 5). Since Ch0 I-data is sampled at the center of the low pulse (e.g., the point 604) the Ch1 I-data is sampled at the middle of the high pulse (e.g., the point 608), the sampled I-data are out of phase by 180°. The synch controller 320 can then compare the values of the sampled I-data. If they values are different as shown in the example of FIG. 6 (e.g., one or more are high while the rest are low), the synch controller 320 can flip the phase of one or more of the LO chains 310 by sending a flip command (e.g., the phase flip 312) to one or more of the LO dividers 304. The phase flip 312 is illustrated at point 612 where a phase flip 312 command is sent to the LO divider 304b to flip the phase of the LO chain 310b (e.g., Ch1). The phase flip of Ch1 is shown by a bracket at point 614. After the phase of Ch1 is flipped, both Ch0 and Ch1 I-data are then sampled in sync. The synch controller 320 can then send the PhaseSyncDone signal 344 at point 616, completing the process of synchronizing multiple LO chains 310.

While two LO chains 310 are used to describe the disclosed methods, it should be noted that the disclosed method can be used to calibrate and synchronize any number of LO chains 310. Accordingly, this disclosure is not so limited.

Although embodiments of the disclosure are described above for particular embodiments, many variations of the disclosure are possible. For example, the numbers of various components may be increased or decreased, modules and blocks that determine a supply or input voltage or signal may be modified to determine a frequency, another system parameter, or a combination of parameters. Additionally, features of the various embodiments may be combined in combinations that differ from those described above.

Those of skill will appreciate that the various illustrative blocks described in connection with the embodiments disclosed herein can be implemented in various forms. Some blocks have been described above generally in terms of their functionality. How such functionality is implemented depends upon the design constraints imposed on an overall system. Skilled persons can implement the described functionality in varying ways for each particular application, but such implementation decisions should not be interpreted as causing a departure from the scope of the disclosure. In addition, the grouping of functions within a block or block is for ease of description. Specific functions or blocks can be moved from one block or distributed across to blocks without departing from the present disclosure.

The various illustrative logical blocks described in connection with the embodiments disclosed herein, such as, for example, the synch controller 320 and the delay controllers 334, can be implemented or performed with a general purpose processor, a digital signal processor (DSP), application specific integrated circuit (ASIC), a field programmable gate array (FPGA) or other programmable logic device, discrete gate or transistor logic, discrete hardware components, or any combination thereof designed to perform the functions described herein. A general-purpose processor can be a microprocessor, but in the alternative, the processor can be any processor, controller (e.g., the synch controller 320, delay controllers 334, sample clock generator 322 as disclosed herein), microcontroller, or state machine. A processor can also be implemented as a combination of computing devices, for example, a combination of a DSP and a microprocessor, a plurality of microprocessors, one or more microprocessors in conjunction with a DSP core, embodied in a System on Chip (SoC), or any other such configuration.

The blocks of a method or algorithm described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of storage medium. An exemplary storage medium can be coupled to the processor such that the processor can read information from, and write information to, the storage medium. In the alternative, the storage medium can be integral to the processor. The processor and the storage medium can reside in an ASIC.

The above description of the disclosed embodiments is provided to enable any person skilled in the art to make or use the present disclosure. Various modifications to these embodiments will be readily apparent to those skilled in the art, and the generic principles described herein can be applied to other embodiments without departing from the spirit or scope of the present disclosure. Thus, it is to be understood that the description and drawings presented herein represent a presently preferred embodiment of the present disclosure and are therefore representative of the subject matter which is broadly contemplated by the present disclosure. It is further understood that the scope of the present disclosure fully encompasses other embodiments that may become obvious to those skilled in the art and that the scope of the present disclosure is accordingly limited by nothing other than the appended claims.

What is claimed is:

1. A method for local oscillator (LO) phase synchronization, the method comprising:
sampling first I-data and first Q-data from an input signal to generate first sampled I-data and first sampled Q-data based on a sampling clock signal;
calibrating the sampling clock signal based on the first sampled I-data and the first sampled Q-data to generate a first calibrated sampling clock signal, the first calibrated sampling clock signal indicating an optimal sample position to sample the first I-data and the first Q-data; and
synchronizing a phase of a first LO chain and a second LO chain based on the first calibrated sampling clock signal.

2. The method of claim 1 further comprising:
sampling second I-data and second Q-data from the input signal to generate second sampled I-data and second sampled Q-data based on the sampling clock signal;
calibrating the sampling clock signal based on the second sampled I-data and the second sampled Q-data to generate a second calibrated sampling clock signal; and
synchronizing the phase of the first LO chain and the second LO chain further based on the second calibrated sampling clock signal.

3. The method of claim 2 further comprising:
dividing the input signal into the first I-data and the first Q-data; and
dividing the input signal into the second I-data and the second Q-data.

4. The method of claim 2, wherein the synchronizing comprises flipping a phase of one of the first LO chain and the second LO chain by 180 degrees.

5. The method of claim 3 further comprising:
dividing the input signal into third I-data and third Q-data for a third LO chain;
calibrating the sampling clock signal using one or more delay increments to determine the optimal sample position of the third I-data and the third Q-data; and
synchronizing the third LO chain with the first LO chain and the second LO chain.

6. The method of claim 2 further comprising calibrating the sampling clock signal for the first LO chain using a first time delay and calibrating the sampling clock signal for the second LO chain using a second time delay.

7. The method of claim 2, wherein the calibrating comprises delaying the sampling clock signal by one or more delay increments for the first LO chain and one or more delay increments for the second LO chain.

8. The method of claim 7, wherein the calibrating further comprises saving the one or more delay increments in a memory and comparing values of two or more samples of at least one of the first I-data and the first Q-data taken at the one or more delay increments to indicate the optimal sample position for the first I-data and the first Q-data.

9. The method of claim 2, wherein the first I-data and first Q-data for the first LO chain is out of phase with the second I-data and the second Q-data for the second LO chain.

10. The method of claim 3, wherein dividing the input signal comprises dividing a frequency of the input signal in half with a divide-by-two LO divider for each of the first LO chain and the second LO chain, the input signal being supplied by a voltage controlled oscillator (VCO).

11. The method of claim 1 further comprising determining the optimal sample position for the first I-data based on a transition point of the first Q-data, the transition point being a point at which a value of the first Q-data changes between binary values.

12. The method of claim 1 further comprising determining the optimal sample position for the first Q-data based on a transition point of the first I-data, the transition point being a point at which a value of the first I-data changes between binary values.

13. The method of claim 1, wherein the calibrating comprises sampling the first I-data and the first Q-data based on the sampling clock signal without adding any delay increments.

14. A device for local oscillator (LO) phase synchronization, the device comprising:
a plurality of samplers configured to sample first I-data and first Q-data for a first LO chain to generate first sampled I-data and first sampled Q-data based on a sampling clock signal; and
a controller operably coupled the plurality of samplers, the controller being configured to
calibrate the sampling clock signal based on the first sampled I-data and the first sampled Q-data to generate a first calibrated sampling clock signal, the first calibrated sampling clock signal indicating an optimal sample position of the first I-data and the first Q-data, and
synchronize a phase of the first LO chain and a second LO chain based on the first calibrated sampling clock signal.

15. The device of claim 14 further comprising:
a plurality of samplers configured to sample second I-data and second Q-data for the second LO chain to generate second sampled I-data and second sampled Q-data based on a sampling clock signal,
wherein the controller is further configured to:
calibrate the sampling clock signal based on the second sampled I-data and the second sampled Q-data to generate a second calibrated sampling clock signal, the second calibrated sampling clock signal indicating an optimal sampling position to sample the second I-data and the second Q-data; and
synchronize the phase of the first LO chain and the second LO chain further based on the second calibrated sampling clock signal.

16. The device of claim 15, wherein the controller is further configured to flip a phase of one of the first LO chain and the second LO chain by 180 degrees.

17. The device of claim 15 further comprising:
a first LO divider configured to divide an input signal into the first I-data and the first Q-data; and
a second LO divider configured to divide the input signal into the second I-data and the second Q-data.

18. The device of claim 17 further comprising:
a third LO divider configured to divide the input signal into third I-data and third Q-data for a third LO chain;
wherein the controller is further configured to calibrate the sampling clock signal using one or more delay increments to determine the optimal sample position of the third I-data and the third Q-data; and
synchronize the third LO chain with the first LO chain and the second LO chain.

19. The device of claim 15 wherein the controller is further configured to calibrate the sampling clock signal for the first LO chain using a first time delay and calibrate the sampling clock signal for the second LO chain using a second time delay.

20. The device of claim 15, wherein the controller is further configured to delay the sampling clock signal by one or more delay increments for the first LO chain and one or more delay increments for the second LO chain.

21. The device of claim 20 further comprising:
a sample clock generator configured to generate the sampling clock signal; and
a plurality of delay buffers coupled to the sample clock generator, each of delay buffer of the plurality of delay buffers configured to output a delayed sampling clock signal with a delay associated with one of the one or more delay increments,
wherein the controller is further configured to select one or more of the delay buffers associated with the one or more delay increments in a memory and compare values of two or more samples of the first I-data and the first Q-data taken at the one or more delay increments to indicate the optimal sample position for the first I-data and the first Q-data.

22. The device of claim 15, wherein the first I-data and first Q-data for the first LO chain are out of phase with the second I-data and the second Q-data for the second LO chain.

23. The device of claim 17, wherein the first LO divider and the second LO divider are configured to divide a frequency of the input signal in half with a divide-by-two frequency divider for the first LO chain and the second LO chain, the input signal being supplied by a voltage-controlled oscillator (VCO).

24. The device of claim 14 wherein the controller is further configured to determine the optimal sample position for the first I-data based on a transition point of the first Q-data, the transition point being a point at which a value of the first Q-data changes between binary values.

25. The device of claim 14, wherein the controller is further configured to determine the optimal sample position for the first Q-data based on a transition point of first I-data, the transition point being a point at which a value of the first I-data changes between binary values.

26. An apparatus for local oscillator (LO) phase synchronization, the apparatus comprising:
means for sampling first I-data and first Q-data for a first LO chain to generate first sampled I-data and first sampled Q-data based on a sampling clock signal;
means for sampling second I-data and second Q-data for a second LO chain to generate second sampled I-data and second sampled Q-data based on the sampling clock signal;
means for calibrating the sampling clock signal based on the first sampled I-data and the first sampled Q-data to generate a first calibrated sampling clock signal, the means for calibrating further configured to calibrate the sampling clock signal based on the second sampled I-data and the second sampled Q-data to generate a second calibrated sampling clock signal; and
means for synchronizing a phase of the first LO chain and the second LO chain based on the first calibrated sampling clock signal.

27. The apparatus of claim 26 further comprising:
means for dividing an input signal into the first I-data and the first Q-data for the first LO chain and the second I-data and the second Q-data for the second LO chain.

28. A method for local oscillator (LO) phase synchronization, the method comprising:
dividing an input signal into I-data and Q-data for each of a first LO chain and a second LO chain using a respective first LO divider and second LO divider, the I-data and the Q-data of the first LO chain having a first phase and the I-data and the Q-data of the second LO chain having a second phase;
sampling the I-data and the Q-data of the first LO chain and the second LO chain to generate sampled I-data and sampled Q-data for each of the first LO chain and the second LO chain based on a sampling clock signal;
calibrating the sampling clock signal based the sampled I-data and the sampled Q-data for each of the first LO chain and the second LO chain to generate a first calibrated sampling clock signal for the first LO chain, and a second calibrated sampling clock signal for the second LO chain; and
synchronizing the first phase and the second phase based on the first calibrated sampling clock signal and the second calibrated sampling clock signal by flipping one of the first phase and the second phase.

29. The method of claim 28 further comprising:
sampling at least one of the I-data and the Q-data of:
the first LO chain base on the first calibrated sampling clock signal; and
the second LO chain based on the second calibrated sampling clock signal; and
comparing the sampled at least one of the I-data and the Q-data of the first and second LO chains, and:
when the sampled at least one of the I-data and the Q-data of the first and second LO chains comprise different values, flip the phase of the one of the first and second LO chains at the respective one of the first and second LO dividers by 180 degrees; and
when the sampled at least one of the I-data and the Q-data of the first and second LO chains comprise a same value, keep the phase at the first and second LO dividers unchanged.

30. The method of claim 28 further comprising calibrating the sampling clock signal further based on an optimal sample position of the sampled I-data and the sampled Q-data for each of the first LO chain and the second LO chain, the optimal sample position corresponding to a center of a data pulse for I-data and the Q-data of the first LO chain and the second LO chain.
